(19) United States
(12) Patent Application Publication
(10) Pub. No.: US 2025/0212661 A1
(43) Pub. Date: Jun. 26, 2025

(54) DISPLAY APPARATUS

(71) Applicant: LG Display Co., Ltd., Seoul (KR)

(72) Inventor: Chiheon Kim, Goyang-si (KR)

(73) Assignee: LG Display Co., Ltd., Seoul (KR)

(21) Appl. No.: 18/958,614

(22) Filed: Nov. 25, 2024

(30) Foreign Application Priority Data
Dec. 20, 2023 (KR) 10-2023-0187206

(51) Int. Cl. H10K 59/80; H10K 59/40

(52) U.S. Cl. CPC H10K 59/874; H10K 59/40

(57) ABSTRACT

Disclosed is a display apparatus including a display area located on a substrate and including a plurality of light-emitting elements, a through-hole area located within the display area, wherein a through-hole extending through the substrate is located in the through-hole area, and a hole boundary area located between the through-hole area and the display area, wherein the display apparatus includes a dam pattern located on the hole boundary area between the through-hole and the display area, an outer barrier pattern disposed between the through-hole and the dam pattern, and an inner barrier pattern disposed between the dam pattern and the display area, wherein the inner barrier pattern has a trench groove including a bottom surface and a sidewall surrounding the bottom surface.

### CROSS-REFERENCE TO RELATED APPLICATION

This application claims priority from Korean Patent Application No. 10-2023-0187206 filed on Dec. 20, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display apparatus, and particularly to, for example, without limitation, a display apparatus that includes a barrier pattern that may prevent or reduce external moisture or oxygen from penetrating into a display area via a through-hole defined within the display area.

### Discussion of the Related Art

A display apparatus is applied to various electronic devices such as a TV, a smartphone, a laptop, and a tablet. To this end, research is continuing to develop a display device that is thinner, lighter, and has lower power consumption.

Examples of the display apparatus may include a liquid crystal display (LCD) device, a field emission display (FED) device, and an organic light emitting display (OLED) device.

Recently, as uses of the display apparatus have become more diverse, electronic components are being provided to provide various functions to a user. For example, the smartphone, the laptop, the tablet, and the like may include a camera for taking photos or images or various sensor devices for detecting an external object as the electronic components. The sensor device may include at least one of a proximity sensor, a gesture sensor, a color sensor, a biometric sensor, and an infrared sensor.

Furthermore, as research continues to increase an area size occupied by a display area where an image is displayed in the display device, importance of a technology for placing the camera or the sensor devices within the display area is increasing. By placing the camera or the sensor devices within the display area, a bezel area, which is a non-display area, may be reduced. When the bezel area, which is the non-display area, is reduced, the area size of the display area increases, which has an advantage of improving user's sense of immersion for the image displayed on the display device.

The description provided in the background section should not be assumed to be prior art merely because it is mentioned in or associated with the background section. The background section may include information that describes one or more aspects of the subject technology.

### SUMMARY

To place the electronic components within the display area, a through-hole should be defined within the display area. However, the through-hole defined in the display device may become a path for external moisture or oxygen to penetrate into the display area. Light-emitting elements to display the image are disposed in the display area, and the light-emitting elements include an organic material that is vulnerable to moisture.

When the light-emitting element is damaged by the external moisture or oxygen penetrated into the display area via the through-hole defined in the display device, a defect such as a dark spot where a pixel does not emit light may occur or reliability of the display device may decrease as luminance of the light-emitting element decreases. Accordingly, research is continuing on a way to block the external moisture or oxygen that has entered the through-hole of the display device from penetrating into the display area.

Therefore, the inventors of the present disclosure recognized the problems mentioned above and other limitations associated with the related art, and conducted various experiments to implement a display apparatus that includes a barrier pattern that may prevent or reduce external moisture or oxygen from penetrating into a display area through a through-hole defined within the display area or delay a diffusion time thereof.

Accordingly, embodiments of the present disclosure are directed to a display apparatus that substantially obviates one or more of the problems due to limitations and disadvantages of the related art.

An aspect of the present disclosure is to provide a display apparatus that may prevent or reduce a light-emitting element within a display area from being damaged by moisture or oxygen penetrating from the outside.

Another aspect of the present disclosure is to provide a display apparatus that may block penetration of external moisture or oxygen through a through-hole or delay a diffusion time thereof, thereby preventing or reducing a dark spot defect or a decrease in luminance.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display area located on a substrate and including a plurality of light-emitting elements, a first region located within the display area and including a hole, and a second region located between the first region and the display area, wherein the display apparatus includes a dam pattern located on the second region between the through-hole and the display area, an outer barrier pattern disposed between the through-hole and the dam pattern, and an inner barrier pattern disposed between the dam pattern and the display area, and each of the inner barrier pattern and the outer barrier pattern has an undercut structure.

According to the embodiment of the present disclosure, the display apparatus that may implement a narrow bezel or a zero bezel by defining a through-hole within a display area of the display apparatus may be provided. As an area size of the display area increases because of the narrow bezel or the zero bezel, the sense of immersion of the user in the screen displayed in the display area may be improved.

By placing the barrier pattern on the hole boundary area located between the through-hole and the display area, the penetration of the external moisture or oxygen into the display area may be blocked or reduced.

The barrier pattern may block the diffusion path of the moisture or the oxygen flowing toward the display area by disconnecting the organic light-emitting layer on the hole boundary area. Furthermore, the barrier pattern may delay the diffusion time of the moisture or the oxygen flowing toward the display area by increasing the length of the organic light-emitting layer on the hole boundary area.

According to the embodiment of the present disclosure, provided is the display apparatus that may have the improved reliability and may be operated with the low power to reduce the power consumption by preventing or reducing the external moisture or oxygen from penetrating into the display area to prevent or reduce the occurrence of the defect, such as the dark spot where the pixel does not emit light, and the decrease in the luminance.

Effects of the present disclosure are not limited to the effects mentioned above, and other effects not mentioned will be clearly understood by those skilled in the art from the descriptions below.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and may be incorporated in and constitute a part of this application, illustrate embodiments of the disclosure and together with the description serve to explain various principles of the disclosure.

FIG. 1 is a schematic perspective view of a display apparatus according to one embodiment of the present disclosure.

FIG. 2 is one side cross-sectional view of a display panel in FIG. 1 according to an example embodiment of the present disclosure.

FIG. 3 is a plan view schematically showing a portion of a display panel according to an exampleembodiment of the present disclosure.

FIG. 4 is a plan view schematically showing a portion of a touch unit on a display panel according to an example embodiment of the present disclosure.

FIG. 5 is an enlarged plan view of an area 5 where the through-hole in FIG. 3 is defined according to an example embodiment of the present disclosure.

FIG. 6 is a cross-sectional view taken along a line I-I′ in FIG. 5 according to an example embodiment of the present disclosure.

FIG. 7 is a cross-sectional view showing an embodiment taken along a line II-II′ in FIG. 6 according to an example embodiment of the present disclosure.

FIG. 8 is a cross-sectional view showing another embodiment of a line II-II′ in FIG. 6 according to an example embodiment of the present disclosure.

FIG. 9 is an enlarged cross-sectional view of an area 9 in FIG. 8 according to an example embodiment of the present disclosure.

FIG. 10 is a cross-sectional view showing a variant of a second inner barrier pattern in FIG. 8 according to an example embodiment of the present disclosure.

FIG. 11 is a cross-sectional view showing another variant of a second inner barrier pattern in FIG. 8 according to an example embodiment of the present disclosure.

FIG. 12 is a cross-sectional view showing another embodiment of a line II-II′ in FIG. 6 according to an example embodiment of the present disclosure.

FIG. 13 is an enlarged cross-sectional view of an area 13 in FIG. 12 according to an example embodiment of the present disclosure.

FIG. 14 is a cross-sectional view showing a variant of a third inner barrier pattern in FIG. 12 according to an example embodiment of the present disclosure.

FIG. 15 is a cross-sectional view showing another variant of a third inner barrier pattern in FIG. 12 according to an example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and a method of achieving the advantages and features will become apparent with reference to example embodiments described later in detail together with the accompanying drawings. However, the present disclosure is not limited to the example embodiments as disclosed under, but may be implemented in various different forms. Thus, these example embodiments are set forth only to make the present disclosure complete, and to completely inform the scope of the present disclosure to those of ordinary skill in the technical field to which the present disclosure belongs. Any implementation described herein as an “example” is not necessarily to be construed as preferred or advantageous over other implementations.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless a more limiting term, such as “directly after”, “directly subsequent” or “directly before” is not indicated.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term “display apparatus (or display device)” may include, in a narrow sense, a display device including a liquid crystal module (LCM), an organic light-emitting diode (OLED) module, or a quantum dot (QD) module including a display panel and a driver for driving the display panel. Moreover, the display device may include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display device in accordance with the present disclosure may include, in the narrow sense, a display device itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module including the display panel and the driver may be expressed as “display device” in a narrow sense. The electronic device as a complete product including the LCM, OLED module or QD module may be expressed as “set” device” in a broad sense. For example, the display device in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. However, embodiments of the present disclosure are not limited thereto. The display panel used in the display device according to an embodiment of the present disclosure is not limited to a shape or a size of the display panel.

Hereinafter, embodiments of the present disclosure will be described using the attached drawings. A scale of each of components as shown in the drawings is different from an actual scale thereof for convenience of illustration, and therefore, the present disclosure not limited to the scale as shown in the drawings.

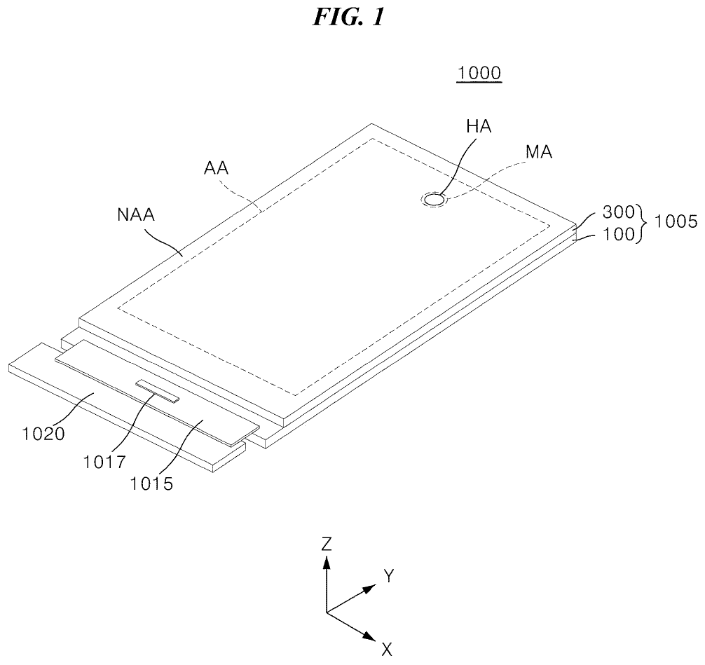

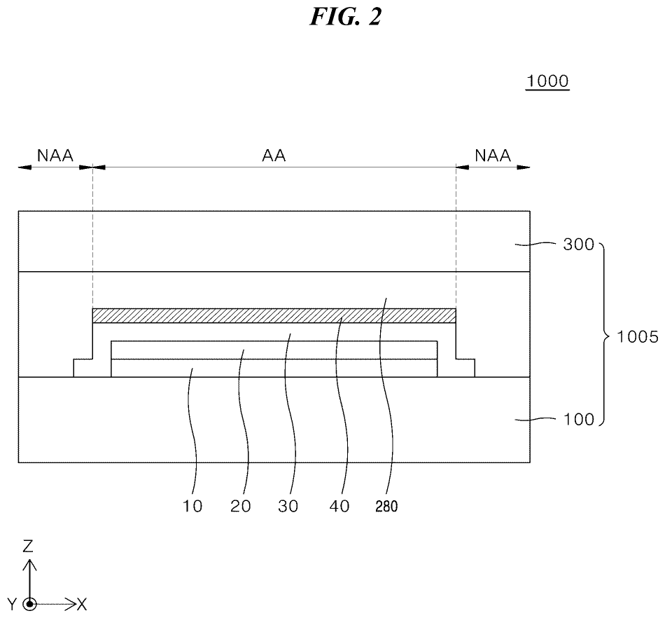

FIG. 1 is a schematic perspective view of a display apparatus according to one embodiment of the present disclosure. FIG. 2 is one side cross-sectional view of a display panel in FIG. 1.

Referring to FIG. 1 and FIG. 2, a display apparatus 1000 according to an embodiment of the present disclosure may include a display panel 1005 having a display area AA and a non-display area NAA located outside the display area AA. For example, the non-display area NAA may be adjacent to the display area AA, or may be disposed to surround the display area AA.

The display panel 1005 includes a first substrate 100 and a second substrate 300. The first substrate 100 may include transparent plastic or glass. The second substrate 300 may include a transparent plastic film, a glass substrate, or an encapsulation film. In a plan view, the first substrate 100 or the second substrate 300 may have a rectangular shape, or may have a rectangular shape with each corner having a rounded shape. The second substrate 300 may be referred to as a cover window, a window cover, or a cover glass that covers the first substrate 100.

The display area AA may have a plurality of pixels arranged. An image may be displayed in the display area AA via the plurality of pixels. In the non-display area NAA, several drivers to operate the plurality of pixels arranged in the display area AA may be disposed. For example, the drivers may include a gate driver, a data driver, a touch driver, and a timing controller, but the present disclosure may not be limited thereto.

A through-hole area HA including a through-hole may be defined in the display area AA. In the drawing, the through-hole area HA is shown as being defined at a center of the display area AA, but the present disclosure is not limited thereto. The through-hole area HA may be an area where electronic components for adding various functions to the display apparatus 1000 are located. For example, the electronic components may include a camera module, a sensor device or other types of optical sensors. The sensor device may include at least one of a proximity sensor, a gesture sensor, a color sensor, a biometric sensor, and an infrared sensor. The through-hole area HA may be an area through which a light signal may be transmitted from the electronic component to the outside of the display apparatus 1000 or light traveling from the outside to the electronic component may be transmitted.

An area between the display area AA and the through-hole area HA may be defined as a hole boundary area MA. The hole boundary area MA may be an area that surrounds the through-hole area HA. One or more light-emitting elements may be disposed or not disposed in the hole boundary area MA. On the hole boundary area MA, barrier patterns that prevent or reduce external moisture or oxygen from penetrating into the display area via the through-hole area HA may be disposed.

The non-display area NAA, which may be an area surrounding the display area AA, may be defined as an area where the image is not displayed. For example, the non-display area NAA may include an upper edge area, a lower edge area, a left edge area, and a right edge area of the display panel 1005. A flexible circuit board 1015 and a printed circuit board 1020 may be disposed on at least one side edge of the non-display area NAA. An integrated circuit chip 1017 may be disposed on the flexible printed circuit board 1015. One side of the flexible circuit board 1015 may be coupled to the first substrate 100, and the other side thereof may be coupled to the printed circuit board 1020 to provide power and various signals for operating the light-emitting element supplied from the printed circuit board 1020 to the display area AA of the first substrate 100. For example, the various signals may include a high potential voltage, a low potential voltage, a scan signal, a data signal, or a touch detection signal.

The printed circuit board 1020 may supply a signal to the integrated circuit chip 1017 disposed on the flexible circuit board 1015. Various components to supply various signals to the integrated circuit chip 1017 may be disposed on the printed circuit board 1020. In FIG. 1, each of the flexible circuit board 1015 and the printed circuit board 1020 is shown to be singular, but the present disclosure is not limited thereto. For example, a plurality of flexible circuit boards 1015 and a plurality of printed circuit boards 1020 may be disposed on one side edge of the first substrate 100.

Referring to FIG. 2, the display panel 1005 may have a structure in which the first substrate 100 and the second substrate 300 are bonded together. A transistor array 10, a light-emitting array 20, an encapsulation portion 30, and a touch unit 40 may be disposed between the first substrate 100 and the second substrate 300. Further, the first substrate 100 and the second substrate 300 may be bonded together via a sealing structure 280. However, the present disclosure is not limited thereto. For example, when the touch sensing function is not integrated into the display panel, the touch unit 40 may be omitted.

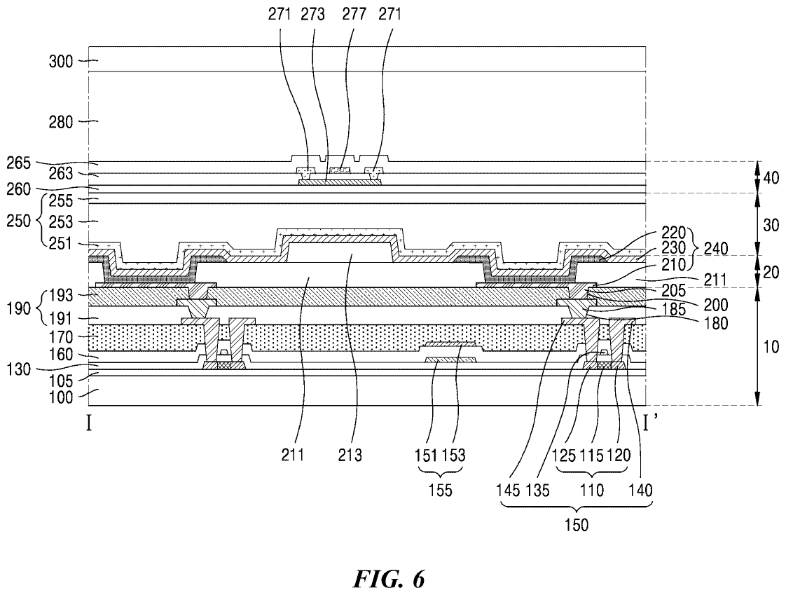

The transistor array 10 may be disposed on the first substrate 100. The transistor array 10 may include a plurality of thin film transistors, a plurality of scan lines, and a plurality of data lines. A detailed description of the transistor array 10 will be made with reference to FIG. 6 below.

The light-emitting array 20 is disposed on the transistor array 10. In the light-emitting array 20, a plurality of light-emitting elements having a stacked structure of a first electrode, a light-emitting layer, and a second electrode may be disposed. The light-emitting layer may be an organic light-emitting layer including an organic material. A driving current may be applied to the first electrode and the second electrode located on and beneath the light-emitting layer, so that the light-emitting layer may emit light. A detailed description of the light-emitting array 20 will be made with reference to FIG. 6 below.

The encapsulation portion 30 may be disposed on the light-emitting array 20. The organic light-emitting layer includes the organic material, and thus, is vulnerable to oxygen and moisture. Accordingly, the encapsulation portion 30 serves to prevent or reduce oxygen or moisture from penetrating by sealing the organic light-emitting layer including the organic material. The encapsulation portion 30 may include an inorganic insulating layer or an organic insulating layer having a multi-layer structure. A detailed description of the encapsulation portion 30 will be made with reference to FIG. 6 below.

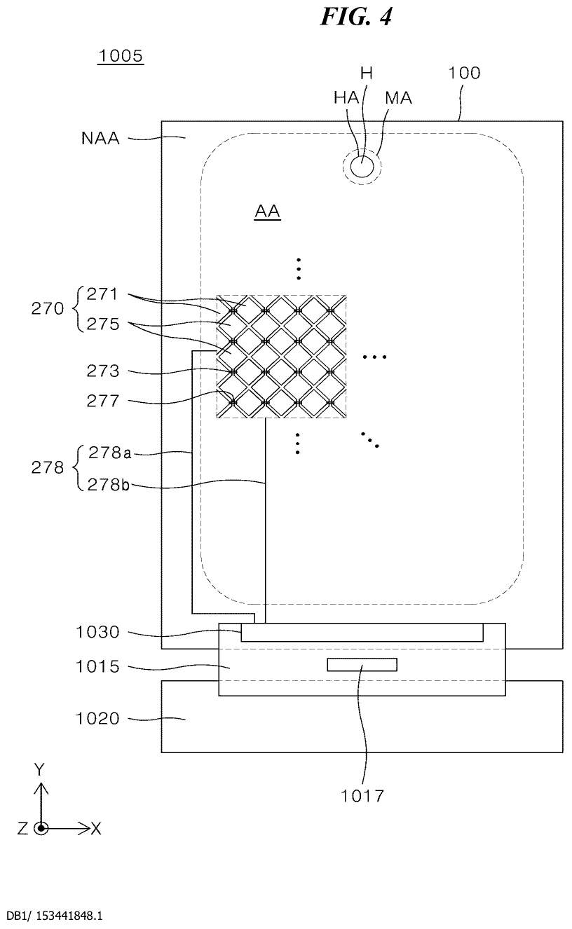

The touch unit 40 may be disposed on the encapsulation portion 30. The touch unit 40 may include a plurality of touch electrodes to detect a user's touch, bridge electrodes to electrically connect adjacent touch electrodes to each other, and a protective layer to protect the touch electrodes. A detailed description of the touch unit 40 will be made with reference to FIGS. 4 and 6 below. The sealing structure 280 covering the touch unit 40 and located between the first substrate 100 and the second substrate 300 may be disposed. The sealing structure 280 may further include an adhesive member that improves adhesion between the first substrate 100 and the second substrate 300.

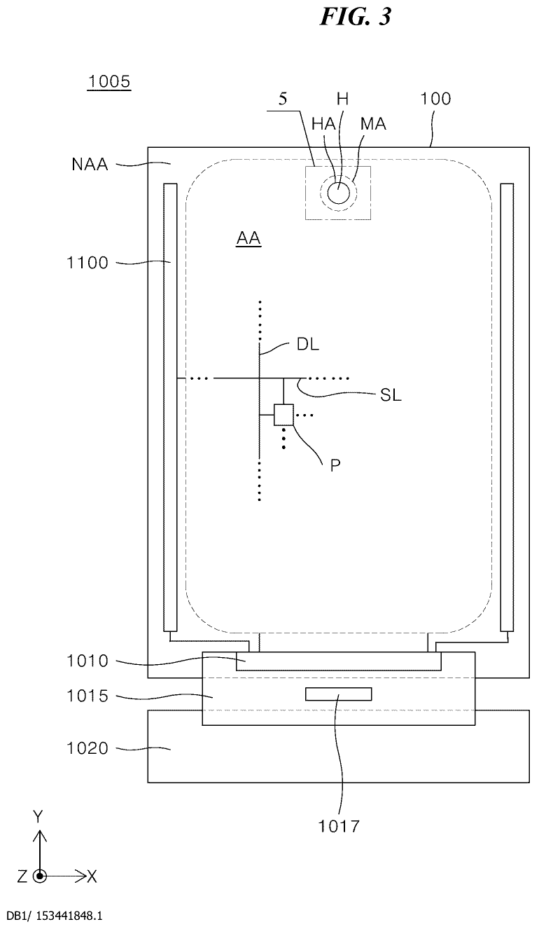

FIG. 3 is a plan view schematically showing a portion of a display panel according to an embodiment of the present disclosure.

Referring to FIGS. 2 and 3, a plurality of data lines DL and a plurality of scan lines SL may be disposed on the display area AA of the first substrate 100. The plurality of data lines DL and the plurality of scan lines SL may be located on the transistor array 10. Each of the plurality of data lines DL may be disposed to intersect each of the plurality of scan lines SL. A pixel P may be defined by the data line DL and the scan line SL intersecting each other, and the plurality of pixels P may be disposed in the display area AA. For example, the single pixel P may be electrically connected to a gate line and the data line.

The single scan line SL extends along a first direction (an X-axis direction) of the first substrate 100. The plurality of scan lines SL may be arranged to be spaced apart from each other in a second direction (a Y-axis direction) that intersects the first direction (the X-axis direction). The single data line DL extends along the second direction (the Y-axis). The plurality of data lines DL may be arranged to be spaced apart from each other in the first direction (the X-axis direction) that intersects the second direction (the Y-axis direction). The first direction may be a horizontal direction of the first substrate 100, and the second direction may be a vertical direction of the first substrate 100, but the present disclosure may not be limited thereto.

The plurality of pixels P may be arranged on the display area AA of the first substrate 100 in a matrix scheme (M*N, where M and N are natural numbers). Each pixel P may have the light-emitting element that may emit red, green, or blue light.

A driver 1100 may be disposed on the non-display area NAA surrounding the display area AA. The driver 1100 may be located on the non-display area NAA at at least one side of the first substrate 100. The driver 1100 may include a gate driver, a data driver, or a timing controller. Furthermore, the driver 1100 may include a power line that supplies power voltage. For example, the gate driver may provide a scan signal to the selected pixels P via the scan line SL, and the data driver may supply a data voltage to the selected pixels P via the data line DL.

A pad 1010 may be located on the non-display area NAA of the first substrate 100 and may include a plurality of electrode pads. For example, the electrode pad included in the pad 1010 may include a plurality of power supply pads, a plurality of data supply pads, and a control signal supply pad or a plurality of common power supply pads for transmitting power and various signals to operate the light-emitting element supplied from the printed circuit board 1020 to the display area AA.

The flexible circuit board 1015 equipped with the integrated circuit chip 1017 may be attached to the pad 1010 disposed on the non-display area NAA of the display panel 1005. In one example, the flexible circuit board 1015 and the pad 1010 may be attached to each other using an anisotropic conductive film. The printed circuit board 1020 may be attached to the other side opposite to one side of the flexible circuit board 1015 to which the pad 1010 is attached. The integrated circuit chip 1017 may be disposed on the flexible printed circuit board 1015. The flexible circuit board 1015 may be coupled with the printed circuit board 1020 to provide the power and the various signals to operate the light-emitting element supplied from the printed circuit board 1020 to the display area AA. For example, the various signals may include a high-potential voltage, a low-potential voltage, a scan signal, a data signal, or a touch driving signal.

FIG. 4 is a plan view schematically showing a portion of a touch unit on a display panel according to an embodiment of the present disclosure.

Referring to FIGS. 2 and 4, a plurality of touch electrodes 270, a plurality of bridge electrodes 273 and 277, and a plurality of touch lines 278 may be disposed in the touch unit 40 of the display panel 1005.

The touch electrodes 270 may include a plurality of first touch electrodes 271 and a plurality of second touch electrodes 275. The plurality of first touch electrodes 271 may be arranged along the first direction (the X-axis direction) of the first substrate 100, and the plurality of second touch electrodes 275 may be arranged along the second direction (the Y-axis direction) that intersects the first direction (the X-axis direction). The first touch electrode 271 and the second touch electrode 275 may be positioned spaced apart from each other. Furthermore, the first touch electrode 271 and the second touch electrode 275 may be disposed to intersect each other. In one example, the plurality of first touch electrodes 271 may be arranged in the first direction the same as the extending direction of the scan line SL (see FIG. 3), and the plurality of second touch electrodes 275 may be arranged in the second direction the same as the extending direction of the data line DL (see FIG. 3).

Each of the plurality of first touch electrodes 271 may be electrically connected to a first touch electrode 271 adjacent thereto via a first bridge electrode 273. Accordingly, the first touch electrodes 271 adjacent to each other may be electrically connected to each other in the X-axis direction, which is the first direction of the first substrate 100. Furthermore, each of the first touch electrodes 271 connected to each other in the X-axis direction, which is the first direction, may be electrically insulated from a first touch electrode 271 adjacent thereto that is disposed to be spaced apart therefrom in the Y-axis direction, which is the second direction.

Furthermore, each of the plurality of second touch electrodes 275 may be electrically connected to a second touch electrode 275 adjacent thereto via a second bridge electrode 277. Accordingly, the second touch electrodes 275 adjacent to each other may be electrically connected to each other in the Y-axis direction, which is the second direction of the first substrate 100. Furthermore, each of the second touch electrodes 275 electrically connected to each other in the Y-axis direction, which is the second direction, may be electrically insulated from a second touch electrode 275 adjacent thereto that is disposed to be spaced apart therefrom in the X-axis direction, which is the first direction.

Referring again to FIG. 4, the plurality of touch electrodes 270 may have a diamond-shaped structure when viewed from a plane, but the present disclosure may not be limited thereto. In one example, the plurality of touch electrodes 270 may include a mesh pattern including thin metal lines intersecting each other. The first touch electrode 271, the second touch electrode 275, the first bridge electrode 273, and the second bridge electrode 277 may be located on a non-light-emitting area. For example, they may be disposed to overlap a bank that defines the non-light-emitting area in the vertical direction. Accordingly, a light-emitting efficiency of a light-emitting area may be prevented or reduced from decreasing.

A touch pad 1030 may be located on the non-display area NAA of the first substrate 100 and may include a plurality of touch electrode pads. The plurality of touch electrode pads may connect the plurality of touch lines 278 with the touch driver. The touch driver may detect a change in a capacitance input from the touch electrodes 270 to detect touch coordinates, and provide a touch driving signal to the touch electrodes 270. In one example, the touch driver may be located on the integrated circuit chip 1017 or the printed circuit board 1020, but the present disclosure may not be limited thereto.

The plurality of touch lines 278 may include a plurality of first touch lines 278a and a plurality of second touch lines 278b. Among the plurality of first touch electrodes 271 electrically connected to each other along the first direction, a first touch electrode 271 disposed at a distal end at one side of the display area AA may be connected to the first touch line 278a. The first touch line 278a may be connected to the touch driver via the touch pad 1030. Accordingly, the first touch electrodes 271 may receive the touch driving signal from the touch driver via the first touch line 278a when the first touch electrodes 271 act as the touch driving electrode, and may transmit the touch sensing signal to the touch driver via the first touch line 278a when the first touch electrodes 271 act as the touch sensing electrode.

Among the plurality of second touch electrodes 275 electrically connected to each other along the second direction, a second touch electrode 275 disposed at a distal end at one side of the display area AA may be connected to the second touch line 278b. The second touch line 278b may be connected to the touch driver via the touch pad 1030. The second touch electrodes 275 may receive the touch driving signal from the touch driver via the second touch line 278b when the second touch electrodes 275 act as the touch driving electrode, and may transmit the touch sensing signal to the touch driver via the second touch line 278b when the second touch electrodes 275 act as the touch sensing electrode. However, the present disclosure is not limited thereto. For example, the touch electrodes shown in FIG. 4 is implemented as a mutual-capacitance based touch sensing structure, but the present disclosure is not limited thereto and the touch electrodes may be applied as a self-capacitance based touch sensing structure.

In one example, the through-hole area HA defined in the display area AA is an area where the through-hole H extending through the first substrate 100 in a direction from a top surface to a bottom surface is defined. The through-hole area HA may be a non-display area or non-emission area as the image is not displayed. The through-hole H may be defined by cutting the first substrate 100 using a laser trimming scheme or metal patterning layer scheme. Accordingly, the external moisture or oxygen may penetrate toward the display area AA via a cross-section exposed by the through-hole H defined via the laser trimming scheme. Accordingly, in an embodiment of the present disclosure, the hole boundary area MA is disposed between the through-hole area HA and the display area AA, and the barrier pattern that prevents or reduces the moisture or the oxygen from penetrating is disposed on the hole boundary area MA. As the barrier pattern is disposed on the hole boundary area MA, the light-emitting element within the display area AA may be prevented or reduced from being damaged by the moisture or the oxygen. Furthermore, by blocking the external moisture or oxygen from penetrating via the through-hole area HA, a defect such as a dark spot may be prevented or reduced from occurring or luminance of the light-emitting element may be prevented or reduced from decreasing.

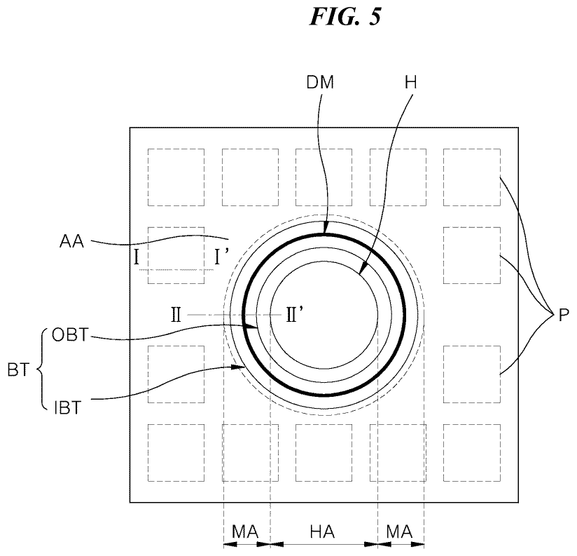

Referring to FIG. 5 below, the area where the through-hole is defined will be described.

FIG. 5 is an enlarged plan view of an area 5 where the through-hole in FIG. 3 is defined.

Referring to FIG. 5 together with FIG. 1, the display area AA of the first substrate 100 may include the through-hole area HA where the through-hole H is defined, and the hole boundary area MA defined between the display area AA and the through-hole area HA. The through-hole H may be positioned through the first substrate 100 in a thickness direction thereof. In a plan view, the through-hole H may have a closed shape. In one example, the through-hole H may have a circular shape, but the present disclosure may not be limited thereto. The hole boundary area MA surrounds the through-hole area HA. Because the pixel P is not disposed in the hole boundary area MA, the hole boundary area MA may be defined as a non-display area or non-emission area. The through-hole area MA may be a first region, and the hole boundary area may be a second region, but the embodiments of the present disclosure are not limited thereto.

A dam pattern DM and a barrier pattern BT may be disposed on the hole boundary area MA. The dam pattern DM may be disposed between the through-hole H and the display area AA. The dam pattern DM may have a closed curve shape surrounding the through-hole H. The dam pattern DM may have a shape the same as that of the through-hole H. In one example, the dam pattern DM may be formed to be disposed outwardly of the through-hole H and surround the through-hole H, so that the dam pattern DM may have a diameter greater than a diameter of the through-hole H. As a result, the dam pattern DM and the through-hole H may be disposed spaced apart from each other.

The barrier pattern BT may include an outer barrier pattern OBT and an inner barrier pattern IBT. The outer barrier pattern OBT may be disposed on a first area between the through-hole H and the dam pattern DM in the hole boundary area MA. The inner barrier pattern IBT may be disposed on a second area between the dam pattern DM and a boundary surface of the display area AA in the hole boundary area MA.

The outer barrier pattern OBT may have a closed curve shape surrounding the through-hole H. The outer barrier pattern OBT may have a shape the same as that of the through-hole H. In one example, the outer barrier pattern OBT is disposed outwardly of the through-hole H and surrounds the through-hole H, so that the outer barrier pattern OBT may have a diameter greater than the diameter of the through-hole H. Accordingly, the outer barrier pattern OBT may be disposed at a location spaced apart from the through-hole H by a predetermined distance. In one example, the outer barrier pattern OBT may include a plurality of patterns.

The inner barrier pattern IBT may have a closed curve shape surrounding the through-hole H. The inner barrier pattern IBT may have a shape the same as that of the through-hole H. In one example, the inner barrier pattern IBT is disposed outwardly of the through-hole H and surrounds the through-hole H, so that the inner barrier pattern IBT may have a diameter greater than the diameter of the through-hole H. Furthermore, as the inner barrier pattern IBT is disposed outwardly of the dam pattern DM and formed to surround the dam pattern DM, the inner barrier pattern IBT may have a size greater than the diameter of the dam pattern DM. Accordingly, the inner barrier pattern IBT may be disposed at a location spaced apart from the through-hole H by a predetermined distance. In one example, the inner barrier pattern IBT may include a plurality of patterns.

Based on the through-hole H, the outer barrier pattern OBT, the dam pattern DM, and the inner barrier pattern IBT may be disposed outwardly of the through-hole H. Accordingly, among the outer barrier pattern OBT, the dam pattern DM, and the inner barrier pattern IBT, the diameter of the outer barrier pattern OBT located closest to the through-hole H may be the smallest and the diameter of the inner barrier pattern IBT located at the greatest distance from the through-hole H may be the greatest.

By placing the dam pattern DM, the outer barrier pattern OBT, and the inner barrier pattern IBT on the hole boundary area MA between the through-hole H and the display area AA, the organic light-emitting layer, which is the component of the light-emitting element, may be separated or disconnected from the hole boundary area MA. By separating or disconnecting the organic light-emitting layer from the hole boundary area MA, diffusion of the moisture or the oxygen that may penetrate via the through-hole H into the display area AA may be prevented, reduced or delayed.

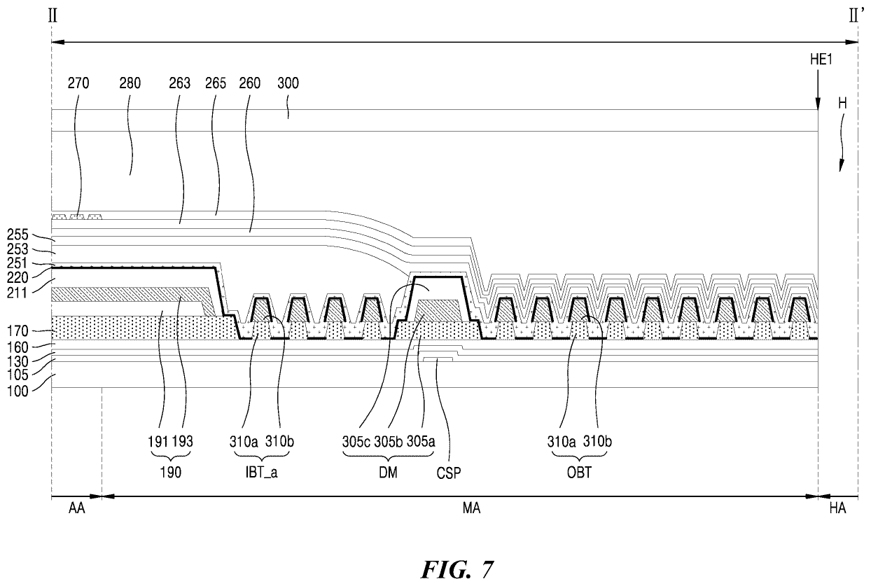

Hereinafter, with reference to FIGS. 6 and 7, a display apparatus including the dam pattern DM and the barrier pattern BT according to embodiments of the present disclosure will be described.

FIG. 6 is a cross-sectional view taken along a line I-I′ in FIG. 5. FIG. 7 is a cross-sectional view showing an embodiment taken along a line II-II′ in FIG. 6.

Referring to FIGS. 6 and 7, a thin film transistor 150 may be disposed on the first substrate 100. The thin film transistor 150 may include a semiconductor layer 110, a gate insulating layer 130, a gate electrode 135, a source electrode 140, and a drain electrode 145. The gate insulating layer 130 may be disposed between the semiconductor layer 110 and the gate electrode 135.

A buffer layer 105 may be disposed between the first substrate 100 and the thin film transistor 150. The buffer layer 105 may cover an entirety of a surface of the first substrate 100. The buffer layer 105 may reduce or prevent the penetration of the moisture or impurities through the first substrate 100. As a result, the thin film transistor 150 may be protected from the moisture penetrating through the first substrate 100. In the drawing, the buffer layer 105 is shown as a single layer, but the buffer layer 105 may include multiple layers. The buffer layer 105 may include an inorganic insulating film including silicon oxide (SiOx) or silicon nitride (SiNx). For example, the buffer layer 105 may include a single layer of an inorganic insulating film or multiple layers in which one or more inorganic insulating films are alternately stacked, but the present disclosure may not be limited thereto.

The semiconductor layer 110 is disposed on the buffer layer 105. The semiconductor layer 110 may be made of an oxide semiconductor or a silicon-based semiconductor material. For example, the semiconductor layer 110 may include a transparent oxide semiconductor material such as indium-gallium-zinc-oxide (IGZO) or indium-zinc-oxide (IZO). Furthermore, the semiconductor layer 110 may include a polysilicon semiconductor material. The semiconductor layer 110 may include a channel area 115, a source area 120, and a drain area 125. The gate insulating layer 130 may include a single layer or a plurality of layers of silicon oxide (SiOx) or silicon nitride (SiNx), but the present disclosure may not be limited thereto. A light blocking layer disposed between the buffer layer 105 and the semiconductor layer 110 or between the first substrate 100 and the buffer layer 105 may be further included to block external light incident on the semiconductor layer 110.

The gate insulating layer 130 may be disposed between the semiconductor layer 110 and the gate electrode 135. Accordingly, a top surface and both side surfaces of the semiconductor layer 110 disposed in a lower portion of the thin film transistor 150 are not exposed to the outside.

On the gate insulating layer 130, the gate electrode 135 and a first capacitor electrode 151 may be disposed on the same layer. An area of the semiconductor layer 110 that overlaps the gate electrode 135 in the vertical direction may be a channel area 115. A source area 120 and a drain area 125 may be located on both sides of the channel area 115. When the semiconductor layer 110 includes an oxide semiconductor material, the source area 120 and the drain area 125 may be conductive areas.

The gate electrode 135 or the first capacitor electrode 151 may include a single layer or multiple layers made of one of molybdenum (Mo), aluminum (Al), chromium (Cr), gold (Au), titanium (Ti), nickel (Ni), neodymium (Nd), and copper (Cu), or an alloy thereof.

An interlayer insulating layer 160 may be disposed on the gate electrode 135 and the first capacitor electrode 151. A second capacitor electrode 153 may be disposed on the interlayer insulating layer 160. The second capacitor electrode 153 may be disposed to overlap the first capacitor electrode 151 in the vertical direction using the interlayer insulating layer 160 as a dielectric to constitute the storage capacitor 155. The second capacitor electrode 153 mayinclude a single layer or multiple layers made of one of molybdenum (Mo), aluminum (Al), chromium (Cr), gold (Au), titanium (Ti), nickel (Ni), neodymium (Nd), and copper (Cu), or an alloy thereof. Additionally, the second capacitor electrode 153 may include transparent conductive oxide. In the drawing, for convenience of description, the single thin film transistor and the single storage capacitor 155 are shown, but the present disclosure is not limited thereto. For example, a plurality of thin film transistors and a plurality of storage capacitors may be disposed.

A passivation layer 170 may be disposed on the interlayer insulating layer 160. The source electrode 140 and the drain electrode 145 that fills a contact hole extending through the interlayer insulating layer 160, the passivation layer 170, and the gate insulating layer 130 may be disposed. The source electrode 140 and the drain electrode 145 may be disposed on both sides with the gate electrode 135 interposed therebetween and may be connected to the source area 120 and the drain area 125 of the semiconductor layer 110, respectively. The source electrode 140 and the drain electrode 145 may be disposed to cover a portion of a top surface of the passivation layer 170. The passivation layer 170 may insulate the thin film transistor 150 and may include a single or a plurality of inorganic insulating layers such as silicon oxide (SiOx) or silicon nitride (SiNx), but the present disclosure may not be limited thereto.

A planarization layer 190 may be disposed on the passivation layer 170, the source electrode 140, and the drain electrode 145. The planarization layer 190 may include a first planarization layer 191 and a second planarization layer 193. The planarization layer 190 serves to planarize a step caused by a lower circuit element including the thin film transistor 150. The planarization layer 190 may include an organic insulating material such as acryl resin, epoxy resin, phenolic resin, polyamide resin, or polyimide resin. However, the present disclosure may not be limited thereto, and the planarization layer 190 may include an organic insulating material that may planarize the step.

The first planarization layer 191 may include a first contact hole 180 extending through the first planarization layer 191 while exposing a portion of a surface of the drain electrode 145 of the thin film transistor 150, but the present disclosure may not be limited thereto. For example, a portion of a surface of the source electrode 140 instead of the drain electrode 145 may be exposed by the first contact hole 180. A first contact electrode 185 may fill the first contact hole 180 while one surface thereof is in contact with the drain electrode 145. The second planarization layer 193 may include a contact hole extending through the second planarization layer 193 while exposing a portion of a surface of the first contact electrode 185. A contact hole 200 extending through the second planarization layer 193 may be filled with a second contact electrode 205, and one surface of the second contact electrode 205 may be in contact with and electrically connected to the first contact electrode 185.

The light-emitting array 20 may be disposed on the planarization layer 190. The light-emitting array 20 may include a bank 211, a plurality of light-emitting elements 240, and a spacer 213. Each of the plurality of light-emitting elements 240 may include a first electrode 210, an organic light-emitting layer 220, and a second electrode 230. Here, the first electrode 210 may also be referred to as an anode electrode or a pixel electrode, and the second electrode 230 may also be referred to as a cathode electrode or an opposing electrode.

The first electrode 210 may be located on the second planarization layer 193. One surface of the first electrode 210 is in contact with a top surface of the second contact electrode 205. Accordingly, the first electrode 210 may be electrically connected to the drain electrode 145 of the thin film transistor 150 via the second contact electrode 205 and the first contact electrode 185.

The first electrode 210 may include transparent metal oxides such as indium tin oxide (ITO) or indium zinc oxide (IZO). Alternatively, the first electrode 210 may have a single-layer or multi-layer structure including a reflective metal film made of silver (Ag), aluminum (Al), gold (Au), nickel (Ni), chromium (Cr), and a compound thereof.

The bank 211 may be disposed on the second planarization layer 193. The bank 211 serves to distinguish each pixel P (see FIG. 5). To this end, the bank 211 may be formed to cover an edge of the first electrode 210. Furthermore, the bank 211 may prevent or reduce light of different colors of pixels adjacent to each other from being mixed with each other and output. The bank 211 may include an organic insulating film such as polyimide or epoxy.

The spacer 213 may be disposed on the bank 211. The spacer 213 may include a material the same as that of the bank 211. The spacer 213 serves to protect the organic light-emitting layer 220 from being directly impacted by an external impact. Furthermore, the spacer 213 serves to provide a separation space to prevent or reduce the first substrate 100 from being in direct contact with a deposition screen mask during a process of depositing the organic light-emitting layer 220.

The organic light-emitting layer 220 may be disposed on the first electrode 210. In one example, the organic light-emitting layer 220 may include an organic material that emits light of different colors in respective sub-pixels. For example, the organic light-emitting layer 220 may emit light of one color among red, green, blue, and white. In another example, the organic light-emitting layer 220 may be made of an organic material that emits white light, and may render one color among red, green, and blue by a color filter.

The organic light-emitting layer 220 may include a stack structure including a hole transport layer (HTL), a light-emitting layer (EML), an electron transport layer (ETL), a hole blocking layer (HBL), a hole injecting layer (HIL), an electron blocking layer (EBL), and an electron injecting layer (EIL). The light-emitting layer EML of the organic light-emitting layer 220 may emit light via recombination of holes injected from the first electrode 210 and electrons injected from the second electrode 230.

In one embodiment, the organic light-emitting layer 220 may be formed to cover a side surface and a portion of a top surface of the bank 211 while surrounding the first electrode 210. In another embodiment, the organic light-emitting layer 220 may be formed throughout the display area AA to cover exposed surfaces of the first electrode 210 and the bank 211. As shown in FIG. 7, the organic light-emitting layer 220 may be formed extending to the display area AA and the hole boundary area MA.

The second electrode 230 may be disposed on the organic light-emitting layer 220. The second electrode 230 may be formed to cover the organic light-emitting layer 220. The second electrode 230 may be commonly formed on the plurality of pixels P. The second electrode 230 may include transparent metal oxide such as indium tin oxide (ITO) or indium zinc oxide (IZO). Alternatively, the second electrode 230 may include a single-layer or multi-layer structure including a reflective metal film made of silver (Ag), aluminum (Al), gold (Au), nickel (Ni), chromium (Cr), and a compound thereof. A capping layer (not shown) may be further included on the second electrode 230. The capping layer may improve an efficiency of light emitted from the light-emitting element 240. For example, the capping layer may include an organic insulating material that may improve a light extraction efficiency.

The encapsulation portion 30 may be disposed on the light-emitting element 240. The encapsulation portion 30 serves to protect the light-emitting element 240 from the external oxygen or moisture. The encapsulation portion 30 may extend to the non-display area NAA surrounding the display area AA while covering the display area AA. The encapsulation portion 30 may include a multi-layer structure in which a first encapsulation layer 251, a second encapsulation layer 253, and a third encapsulation layer 255 are stacked. In one example, the first encapsulation layer 251, the second encapsulation layer 253, and the third encapsulation layer 255 may be disposed to extend to the hole boundary area MA, as shown in FIG. 7.

The first encapsulation layer 251 may be disposed on the light-emitting element layer 240. The first encapsulation layer 251 may include an inorganic insulating material. For example, the first encapsulation layer 251 may include at least one inorganic insulating material selected from silicon nitride (SiNx), silicon oxide (SiOx), or silicon oxynitride (SiON).

The second encapsulation layer 253 may cover the first encapsulation layer 251 and may have a sufficient thickness to have a flat surface. The second encapsulation layer 253 may prevent or reduce the foreign substances from penetrating into the light-emitting element layer 240. The second encapsulation layer 253 may include an organic insulating material. For example, the second encapsulation layer 253 may include at least one material of epoxy, polyimide, polyethylene, or acrylate.

The third encapsulation layer 255 may be disposed on the second encapsulation layer 253. The third encapsulation layer 255 may include an inorganic insulating material. For example, the third encapsulation layer 255 may include at least one inorganic insulating material selected from silicon nitride (SiNx), silicon oxide (SiOx), or silicon oxynitride (SiON).

The touch unit 40 may be disposed on the encapsulation portion 30. The touch unit 40 may include a touch buffer layer 260, a touch insulating layer 263, the plurality of first touch electrodes 271, the plurality of second touch electrodes 275 (see FIG. 4), a plurality of first bridge electrodes 273, and a plurality of second bridge electrodes 277. In one example, the first touch electrode 271, the second touch electrode 275, and the second bridge electrode 277 may be disposed on the same layer. The first bridge electrode 273 may be disposed on a layer different from that of the first touch electrode 271 and the second touch electrode 275.

Referring to FIG. 4 together, the plurality of first touch electrodes 271 and the plurality of second touch electrodes 275 may be positioned spaced apart from each other. The first touch electrode 271 and the second touch electrode 275 may be insulated from each other by a touch protective layer 265. The first bridge electrode 273 may be disposed on the touch buffer layer 260. The first bridge electrode 273 may be covered with the touch insulating layer 263. The touch insulating layer 263 may include a contact hole extending through the touch insulating layer 263 to expose a portion of a surface of the first bridge electrode 273. A plurality of first touch electrodes 271 adjacent to each other may be electrically connected to each other by being connected to the first bridge electrode 273 while filling the contact holes. The first touch electrode 271, the second touch electrode 275, the first bridge electrode 273, and the second bridge electrode 277 may include a single layer or multiple layers made of one of molybdenum (Mo), aluminum (Al), chromium (Cr), gold (Au), titanium (Ti), nickel (Ni), neodymium (Nd), and copper (Cu) or an alloy thereof. Plurality of second touch electrodes 275 (see FIG. 4) adjacent to each other may be electrically connected to each other via the second bridge electrode 277.

The sealing structure 280 may be disposed on the touch unit 40. The sealing structure 280 may have a sufficient thickness to cover a step caused by the touch unit 40 and have a flat surface. The sealing structure 280 may prevent or reduce the foreign substances, the moisture, or the oxygen from penetrating into the touch unit 40. To this end, the sealing structure 280 may include a multi-layer structure in which an organic insulating layer and an inorganic insulating layers are alternately stacked.

The second substrate 300 may be disposed on the sealing structure 280. The second substrate 300 may serve as a cover window or a cover substrate that covers the first substrate 100. The second substrate 300 may include a plastic film or a glass substrate. An adhesive member may be further included between the sealing structure 280 and the second substrate 300. The adhesive member may improve adhesion between the first substrate 100 and the second substrate 300. The adhesive member may include an optically clear resin layer (OCR) or an optically clear adhesive film (OCA). For convenience of description, the second substrate 300 is not shown in FIG. 7. It is to be noted that, although a specific structure of the display area of the display apparatus is shown in FIG. 6, the present application is not limited thereto. For example, one or more elements or layers shown in FIG. 6 may be omitted when necessary.

Referring to FIG. 7 along with FIG. 5, the display apparatus according to an embodiment of the present disclosure may have the dam pattern DM and the barrier pattern BT disposed on the hole boundary area MA. The dam pattern DM prevents or reduces the second encapsulation layer 253, which includes the organic insulating material, from overflowing in a direction of the through-hole H.

The dam pattern DM may include a structure in which a first layer 305a formed in a process of forming the passivation layer 170, a second layer 305b formed in a process of forming the second planarization layer 193, and a third layer 305c formed in a process of forming the bank 211 are stacked in an upward direction. Accordingly, the first layer 305a may include the same inorganic insulating material as that of the passivation layer 170, the second layer 305b may include the same organic insulating material as that of the second planarization layer 193, and the third layer 305c may include the same organic insulating material as that of the bank 211. In an embodiment, the third layer 305c may be formed in a process of forming the spacer 213 (see FIG. 6). The second layer 305b of the dam pattern DM has a size smaller than that of the first layer 305a, so that an edge of a top surface of the second layer 305a may be exposed. The third layer 305c of the dam pattern DM may cover an exposed surface of the first layer 305a while covering the second layer 305b.

A crack detection pattern CSP may be disposed on the first substrate 100. The crack detection pattern CSP may be positioned overlapping the dam pattern DM in the vertical direction. The crack detection line CSP may detect a defect such as a crack that may occur in a process of defining the through-hole H.

As described above, the external moisture or oxygen may penetrate toward the display area AA via the exposed cross-section of the through-hole H defined via the cutting with the laser trimming scheme. In particular, the moisture may penetrate toward the display area AA from a hole end HE1 of the hole boundary area MA. Accordingly, along with the dam pattern DM, the barrier pattern BT that prevents or reduces the external moisture or oxygen from penetrating toward the display area AA may be disposed on the hole boundary area MA.

The barrier pattern BT according to an embodiment of the present disclosure may include the outer barrier pattern OBT and a first inner barrier pattern IBT_a. The outer barrier pattern OBT may be disposed on the first area between the through-hole H and the dam pattern DM in the hole boundary area MA. The first inner barrier pattern IBT_a may be disposed on the second area between the dam pattern DM and the boundary surface of the display area AA in the hole boundary area MA.

The outer barrier pattern OBT may include a stacked structure of a lower structure 310a and an upper structure 310b disposed on the lower structure 310a. The lower structure 310a may be made of the same material as that of the passivation layer 170 in the same process as that of the passivation layer 170. For example, the lower structure 310a may include a single or a plurality of inorganic insulating layers such as silicon oxide (SiOx) or silicon nitride (SiNx). The upper structure 310b may be made of the same material as that of the second planarization layer 193 in the same process as that of the second planarization layer 193. For example, the upper structure 310b may be formed to include an organic insulating material such as acryl resin, epoxy resin, phenolic resin, polyamide resin, or polyimide resin.

The first inner barrier pattern IBT_a may be formed in the same process as that of the outer barrier pattern OBT. Accordingly, the first inner barrier pattern IBT_a may include the stacked structure of the lower structure 310a and the upper structure 310b disposed on the lower structure 310a, in the same way as the outer barrier pattern OBT.

The upper structure 310b of each of the first inner barrier pattern IBT_a and the outer barrier pattern OBT may have a positive taper shape in which a first width of a bottom surface is greater than a second width of a top surface. The lower structure 310a of each of the first inner barrier pattern IBT_a and the outer barrier pattern OBT may have a positive taper shape in which a third width of a bottom surface is greater than a fourth width of a top surface. Furthermore, the first width of the bottom surface of the upper structure 310b of each of the first inner barrier pattern IBT_a and the outer barrier pattern OBT may be greater than the fourth width of the top surface of the lower structure 310a. In other words, an outermost portion of the lower structure 310a of each of the first inner barrier pattern IBT_a and the outer barrier pattern OBT may have an undercut structure that goes inwardly of an outermost portion of the bottom surface of the upper structure 310b. Accordingly, the outermost portion of the bottom surface of the upper structure 310b of each of the first inner barrier pattern IBT_a and the outer barrier pattern OBT may have a shape that protrudes more than the lower structure 310a.

When the organic light-emitting layer 220 is formed with the first inner barrier pattern IBT_a and outer barrier pattern OBT disposed, the organic light-emitting layer 220 may be deposited on a surface of the upper structure 310b of each of the first inner barrier pattern IBT_a and the outer barrier pattern OBT. Furthermore, the organic light-emitting layer 220 may also be deposited on a surface of the interlayer insulating layer 160 exposed between first inner barrier patterns IBT_a adjacent to each other and between outer barrier patterns OBT adjacent to each other. Further, the organic light-emitting layer 220 may also be deposited on an exposed surface of the dam pattern DM. In one example, a length of the organic light-emitting layer 220 deposited along the surface of the upper structure 310b of each of the first inner barrier pattern IBT_a and the outer barrier pattern OBT may be in a range from 8.00 μm to 8.2 μm.

As the lower structure 310a of each of the first inner barrier pattern IBT_a and the outer barrier pattern OBT has the undercut structure that goes inwardly of the outermost portion of the upper structure 310b, the organic light-emitting layer 220 is not applied on a sidewall of the lower structure 310a. Accordingly, as continuity of the organic light-emitting layer 220 is broken, the organic light-emitting layer 220 may be disconnected.

As the organic light-emitting layer 220 is disconnected between the first inner barrier patterns IBT_a adjacent to each other and between the outer barrier patterns OBTs adjacent to each other, the moisture or the oxygen penetrating from the outside may be prevented or reduced from penetrating toward the display area AA or a time when the moisture or the oxygen penetrates toward the display area AA may be delayed.

The first encapsulation layer 251 may be deposited on the organic light-emitting layer 220 of the hole boundary area MA. The first encapsulation layer 251 is deposited to cover the surface of the upper structure 310b and side surfaces of the lower structure 310a of each of the first inner barrier pattern IBT_a and the outer barrier pattern OBT. The first encapsulation layer 251 may cover the surface of the dam pattern DM. The first encapsulation layer 251 may have a shape of filling a space between the first inner barrier patterns IBT_a and a space between the outer barrier patterns OBT, a space between the first inner barrier pattern IBT_a and the dam pattern DM, and a space between the dam pattern DM and the outer barrier pattern OBT.

The second encapsulation layer 253 is disposed on the first encapsulation layer 251. The second encapsulation layer 253 may be formed by extending to the first area of the hole boundary area MA between the display area AA and the dam pattern DM. As the dam pattern DM blocks the overflow of the second encapsulation layer 253, the first inner barrier patterns IBT_a disposed on the first area are covered with the second encapsulation layer 253, but the outer barrier pattern OBT disposed on the second area of the hole boundary area MA is not covered by the second encapsulation layer 253.

The third encapsulation layer 255 may be disposed on the second encapsulation layer 253. The third encapsulation layer 255 may be formed extending from the display area AA to the hole boundary area MA. Accordingly, the second area of the hole boundary area MA where the outer barrier patterns OBT are disposed may be formed in a structure in which the first encapsulation layer 251 and the third encapsulation layer 255 are stacked.

An insulating structure in which the touch buffer layer 260 and the touch insulating layer 263 are stacked may be disposed on the third encapsulation layer 255. The touch buffer layer 260 may include an inorganic insulating material. The plurality of touch lines 278 connected to the plurality of touch electrodes 270 (see FIG. 4) may be disposed on the touch insulating layer 263 of the display area AA.

The sealing structure 280 covering the touch line 278 may be disposed. The sealing structure 280 may prevent or reduce the foreign substances, the moisture, or the oxygen from penetrating into the touch unit 40. The sealing structure 280 may include the multi-layer structure in which the organic insulating layer and the inorganic insulating layer are alternately stacked. The sealing structure 280 may extend from the display area AA to the hole end HE1 of the hole boundary area MA to cover both the first inner barrier pattern IBT_a and the outer barrier pattern OBT.

According to an embodiment of the present disclosure, when the moisture or the oxygen penetrates from the outside through the cross-section of the through-hole H defined using the laser, the penetration of the moisture or the oxygen may be prevented or reduced or a time when the moisture or the oxygen diffuses may be delayed in the hole boundary area MA including the outer barrier pattern OBT, the dam pattern DM, and the first inner barrier pattern IBT_a. For example, the time when the moisture or the oxygen diffuses from the hole end HE1 toward the display area AA may be delayed for a long time by the organic light-emitting layer 220 disconnected on each structure of the outer barrier pattern OBT, the dam pattern DM, and the first inner barrier pattern IBT_a.

In one example, the moisture or the oxygen penetrated from the outside diffuses toward the display area using the organic light-emitting layer, which includes a material vulnerable to the moisture or the oxygen, as a penetration path. Accordingly, a structure that may prevent or reduce the diffusion through the organic light-emitting layer or further delay the diffusion time is needed.

In another embodiment of the present disclosure, a configuration that may prevent or reduce the moisture from diffusing or further delay the diffusion time of the moisture with a shape of the inner barrier pattern will be described.

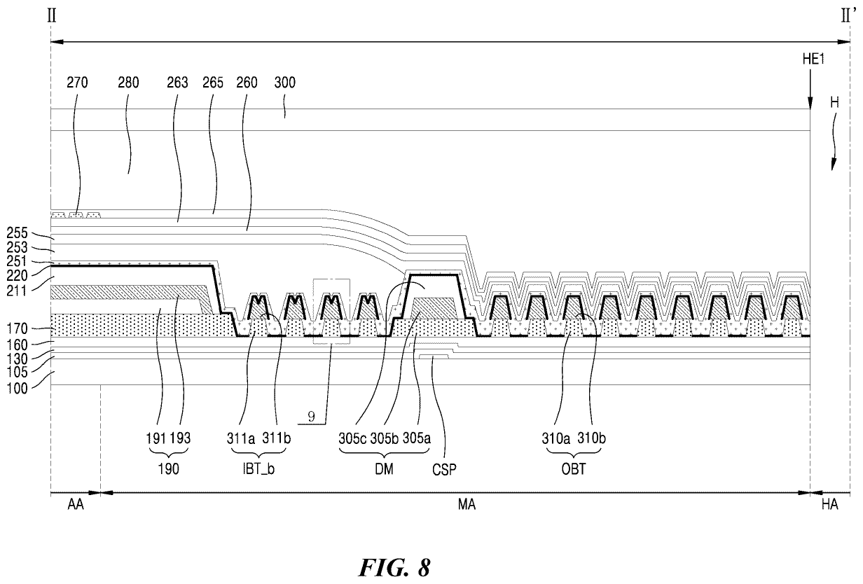

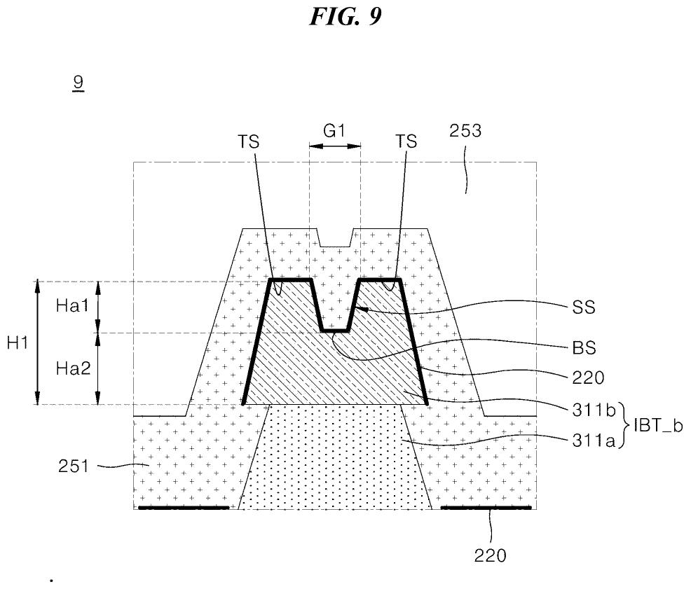

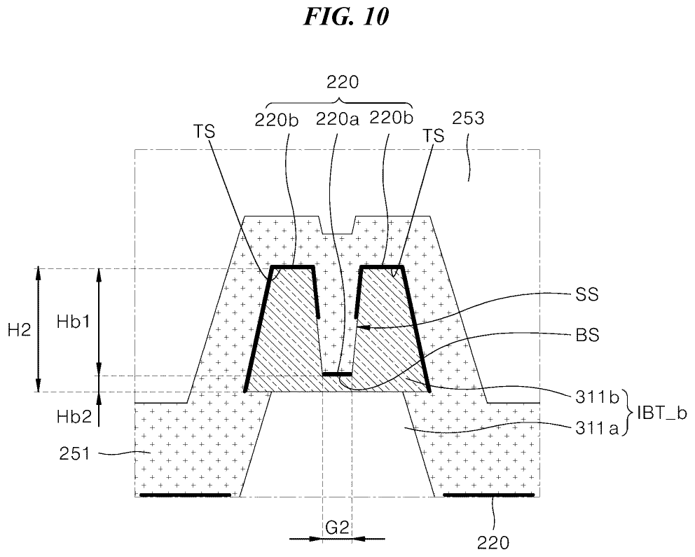

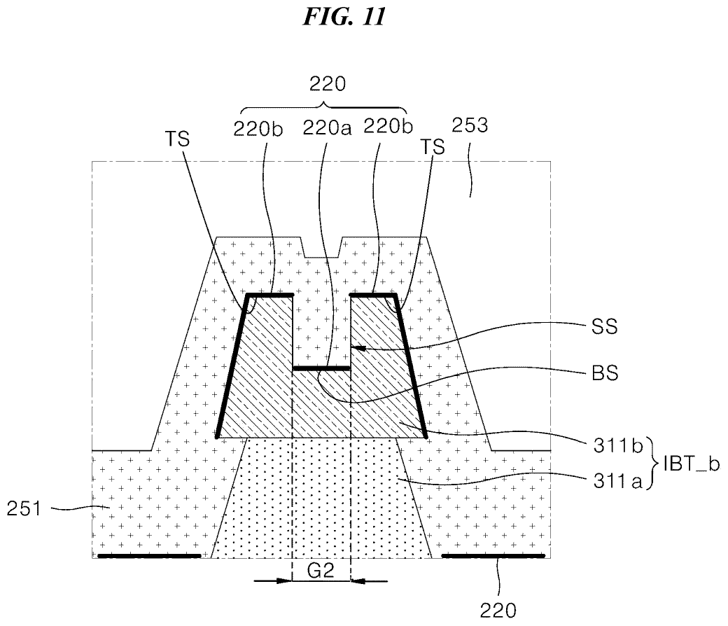

FIG. 8 is a cross-sectional view showing another embodiment of a line II-II′ in FIG. 6. FIG. 9 is an enlarged cross-sectional view of an area 9 in FIG. 8. FIG. 10 is a cross-sectional view showing a variant of a second inner barrier pattern in FIG. 8. Further, FIG. 11 is a cross-sectional view showing another variant of a second inner barrier pattern in FIG. 8.

Because FIG. 8 includes the same configuration as FIG. 7 except for the shape of the inner barrier pattern, redundant descriptions will be omitted or will be made briefly, and a difference will be described. The same reference numerals may indicate the same components.

Referring to FIGS. 8 and 9, the dam pattern DM is disposed on the hole boundary area MA. The plurality of outer barrier patterns OBT may be disposed on the first area of the hole boundary area MA, and the plurality of second inner barrier patterns IBT_b may be disposed on the second area of the hole boundary area MA.

The outer barrier pattern OBT may include the stacked structure of the lower structure 310a and the upper structure 310b. The lower structure 310a of the outer barrier pattern OBT may be formed by being patterned together during the process of forming the passivation layer 170, and the upper structure 310b may be formed by being patterned together during the process of forming the second planarization layer 193.

The second inner barrier pattern IBT_b may include the stacked structure of the lower structure 311a and the upper structure 311b disposed on the lower structure 311a. The lower structure 311a of the second inner barrier pattern IBT_b may be formed by being patterned together in the process of forming the lower structure 310a of the outer barrier pattern OBT. For example, the lower structure 311a of the second inner barrier pattern IBT_b may be formed to include the single or the plurality of inorganic insulating layers such as silicon oxide (SiOx) or silicon nitride (SiNx). The upper structure 311b of the second inner barrier pattern IBT_b may be formed by being patterned together in the process of forming the upper structure 310b of the outer barrier pattern OBT. For example, the upper structure 311b of the second inner barrier pattern IBT_b may be formed to include the organic insulating material such as acryl resin, epoxy resin, phenolic resin, polyamide resin, or polyimide resin.

The upper structure 311b of the second inner barrier pattern IBT_b may include a trench groove G1. In one example, the first trench groove G1 may be defined at a center of the upper structure 311b, but the present disclosure may not be limited thereto. The trench groove G1 may be recessed to have a depth Ha1 from the top surface toward the bottom surface of the upper structure 311b. In a cross-sectional view, the upper structure 311b may include a top surface TS divided into two parts by the trench groove G1, a bottom surface BS of the trench groove G1, and a sidewall SS connecting the bottom surface BS with the top surface TS. The sidewall SS may be an inclined surface that surrounds the bottom surface BS and is inclined outward with respect to the bottom surface BS.

The organic light-emitting layer 220 may be deposited along a surface of the upper structure 311b. In terms of a total thickness H1 of the upper structure 311b, the trench groove G1 may have a depth Ha1 smaller than a distance Ha2 between the bottom surface BS of the trench groove G1 and the bottom surface of the upper structure 311b. Accordingly, the organic light-emitting layer 220 may be deposited to continuously extend along shapes of surfaces of an outer side surface, the top surface TS, the bottom surface BS exposed by the trench groove G1, and the sidewall SS of the upper structure 311b,

According to another embodiment of the present disclosure, the organic light-emitting layer 220 deposited on the surface of the upper structure 311b may have a length in a range from 8.7 μm to 9.1 μm. Accordingly, when defining the length of the organic light-emitting layer deposited on the first inner barrier pattern IBT_a in FIG. 7 as 100%, the second inner barrier pattern IBT_b may have a length of the organic light-emitting layer that is increased by 9% to 10% from that of the first inner barrier pattern IBT_a. In other words, the time when the moisture or the oxygen penetrates toward the display area may be further delayed compared to the case in which the first inner barrier pattern IBT_a is disposed.

The dam pattern DM and the barrier pattern BT disposed on the hole boundary area MA may prevent or reduce the moisture or the oxygen from penetrating toward the display area AA, thereby preventing or reducing the defect such as the dark spot from occurring in the light-emitting element. Further, the decrease in the luminance of the light-emitting element caused by the penetration of the moisture or the oxygen toward the display area may be prevented or reduced, thereby improving the reliability of the display apparatus. In addition, by preventing or reducing the defect in the light-emitting element, a display apparatus with low power consumption may be provided.

The trench groove G1, which is introduced to increase the length of the organic light-emitting layer in the barrier pattern BT, is disposed only in the second inner barrier pattern IBT_b. In other words, it is desirable that the top surface of the upper structure 310b of the outer barrier pattern OBT has a flat surface. On the upper structure 310b of the outer barrier pattern OBT, a structure in which the inorganic insulating materials such as the first encapsulation layer 251, the third encapsulation layer 255, and the touch buffer layer 260 are sequentially stacked may be formed. When the trench groove is defined in the upper structure 310b of the outer barrier pattern OBT, a seam may occur instead of the surface being flat during a process of stacking the inorganic insulating materials within the trench groove. The seam may become a penetration path for gas generated in a subsequent process or may become another penetration path for the moisture or the oxygen penetrated from the through-hole H.

In this regard, the second encapsulation layer 253 including the organic insulating material may be deposited on the first encapsulation layer 251, on the upper structure 310a of the second inner barrier pattern IBT_b. Accordingly, even when the trench groove G1 is defined in the upper structure 311b of the second inner barrier pattern IBT_b, the seam may be prevented or reduced from occurring by the second encapsulation layer 253.

Accordingly, as the first trench groove G1 is defined only in the second inner barrier pattern IBT_b, the outer barrier pattern OBT and the first inner barrier pattern IBT_b having different shapes may be disposed on the hole boundary area MA.

In one example, depending on the depth of the trench groove or the shape of the trench groove defined in the upper structure of the second inner barrier pattern, the portion where the organic light-emitting layer is disconnected may increase, thereby further increasing the effect of blocking the penetration path of the moisture. Hereinafter, this will be described with reference to FIGS. 10 and 11.

Referring to FIG. 10, the second inner barrier pattern IBT_b may include a trench groove G2. The trench groove G2 may be recessed to have a depth Hb1 from the top surface toward the bottom surface of the upper structure 311b. In a cross-sectional view, the upper structure 311b may include the top surface TS divided into two parts by the trench groove G2, the bottom surface BS of the trench groove G2, and the sidewall SS connecting the bottom surface BS with the top surface TS.

The organic light-emitting layer 220 may be deposited along the surface of the upper structure 311b. In a total thickness H2 of the upper structure 311b, the depth Hb1 of the trench groove G2 may be greater than a distance Hb2 between the bottom surface BS of the trench groove G2 and the bottom surface of the upper structure 311b. As the distance between the bottom surface BS of the trench groove G2 and the bottom surface of the upper structure 311b is smaller, a length of the sidewall SS also increases. Accordingly, the organic light-emitting layer 220 may cover a portion of the sidewall SS of the trench groove G2 extending from the top surface TS and expose the remaining portion of the sidewall SS close to the bottom surface BS without covering the same. The organic light-emitting layer 220 may include a first portion 220a covering the bottom surface BS of the trench groove G2 in the upper structure 311b, and a second portion 220b covering a portion of the sidewall SS divided into two parts on both sides with the bottom surface BS interposed therebetween and the top surface TS. In other words, the organic light-emitting layer 220 may be disconnected between the bottom surface BS and the portion of the sidewall SS of the trench groove G2.

Accordingly, the organic light-emitting layer 220 may be not only disconnected between second inner barrier patterns IBT_b adjacent to each other and between outer barrier patterns OBT adjacent to each other, but also disconnected at the top surface TS of the upper structure 311b of the second inner barrier pattern IBT_b. In other words, as an area in which the organic light-emitting layer 220 is disconnected increases, the moisture or the oxygen penetrating from the outside may be prevented or reduced from penetrating toward the display area AA or the time when the moisture or the oxygen penetrates toward the display area AA may be further delayed.

Referring to FIG. 11, in another embodiment, the trench groove G2 of the second inner barrier pattern IBT_b may have the sidewall SS having a vertical surface instead of the inclined surface with respect to the bottom surface BS. In the process of depositing the organic light-emitting layer 220, as the sidewall SS of the trench groove G2 has the vertical surface with respect to the bottom surface BS, the organic light-emitting layer 220 may not be deposited on the sidewall SS of the trench groove G2. Accordingly, the organic light-emitting layer 220 may include the first portion 220a covering the bottom surface BS of the trench groove G2 and the second portion 220b covering the top surface TS divided into the two parts on both sides with the bottom surface BS interposed therebetween in the upper structure 311b. The disconnection length of the organic light-emitting layer 220 may increase as much as the depth of the sidewall SS.

Accordingly, the organic light-emitting layer 220 may be not only disconnected between second inner barrier patterns IBT_b adjacent to each other and between outer barrier patterns OBT adjacent to each other, but also disconnected at the top surface TS of the upper structure 311b of the second inner barrier pattern IBT_b. In other words, as the area in which the organic light-emitting layer 220 is disconnected increases, the moisture or the oxygen penetrating from the outside may be prevented or reduced from penetrating toward the display area AA, or the time when the moisture or the oxygen penetrates toward the display area AA may be further delayed. Furthermore, the length of the disconnected section increases because of the shape of the trench groove G2 in which the sidewall SS has the vertical surface with respect to the bottom surface BS, which may further increase the delay in the time when the moisture penetrates.

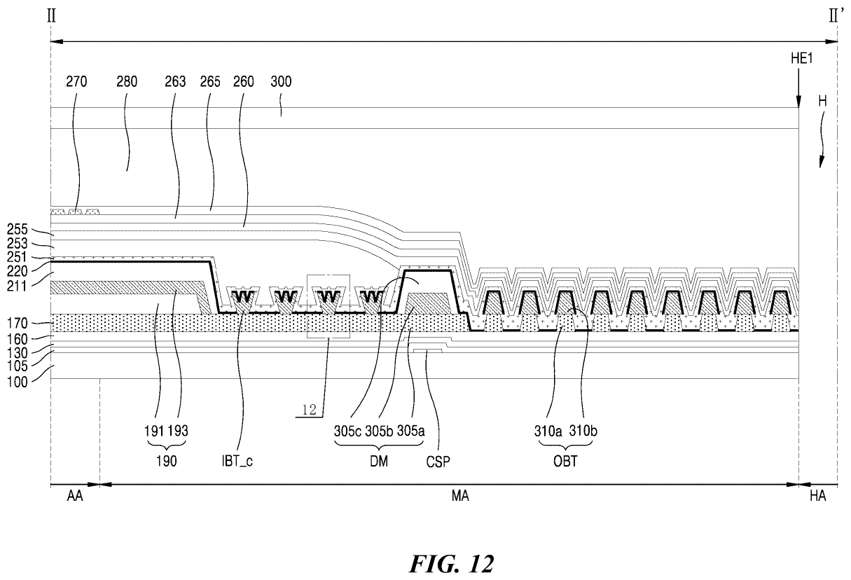

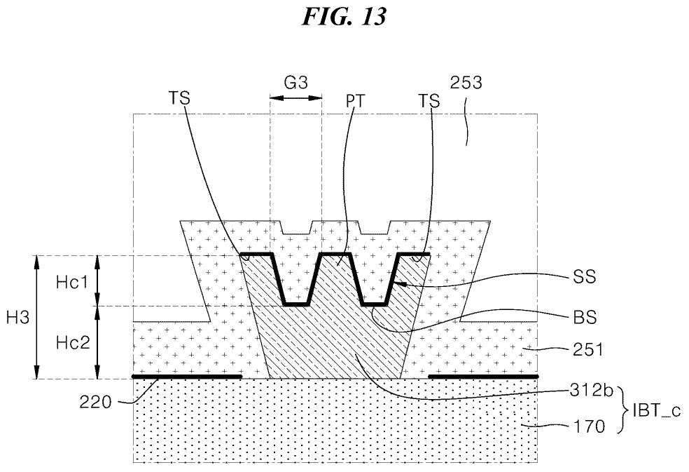

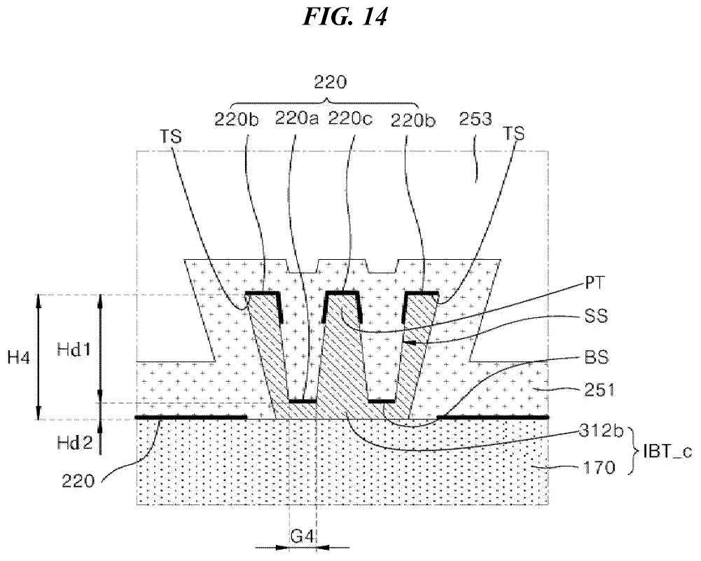

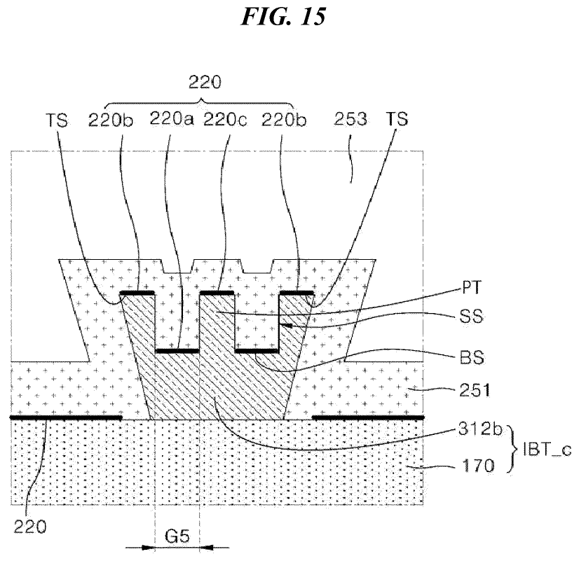

FIG. 12 is a cross-sectional view showing another embodiment of a line II-II′ in FIG. 6. FIG. 13 is an enlarged cross-sectional view of an area 13 in FIG. 12. FIG. 14 is a cross-sectional view showing a variant of a third inner barrier pattern in FIG. 12. Further, FIG. 15 is a cross-sectional view showing another variant of a third inner barrier pattern in FIG. 12.

In FIG. 12, the same components as in FIG. 7 are indicated with the same reference numerals. Accordingly, redundant descriptions will be omitted or briefly made, and a difference will be described.

Referring to FIGS. 12 and 13, the dam pattern DM is disposed on the hole boundary area MA. The plurality of outer barrier patterns OBT may be disposed on the first area within the hole boundary area MA, and a plurality of third inner barrier patterns IBT_c may be disposed on the second area within the hole boundary area MA.

The outer barrier pattern OBT may include the stacked structure of the lower structure 310a and the upper structure 310b. The lower structure 310a of the outer barrier pattern OBT may be formed by being patterned together during the process of forming the passivation layer 170, and the upper structure 310b may be formed by being patterned together during the process of forming the second planarization layer 193.

The dam pattern DM may include the structure in which the first layer 305a formed in the process of forming the passivation layer 170, the second layer 305b formed in the process of forming the second planarization layer 193, and the third layer 305c formed in the process of forming the bank 211 are stacked in the upward direction. In one example, the passivation layer 170 may extend from the display area AA to the hole boundary area MA to constitute the first layer 305a of the dam pattern DM. In this case, there is an advantage of simplifying process steps.

The third inner barrier pattern IBT_c may include the upper structure 312b disposed on the passivation layer 170. Each of the third inner barrier patterns IBT_c may include a structure in which the passivation layer 170 is a lower structure and the upper structures 312b are disposed to be spaced apart from each other on an exposed surface of the passivation layer 170. The upper structure 312b of the third inner barrier pattern IBT_c may include the same material as that of the second planarization layer 193. For example, the upper structure 312b may be formed by including an organic insulating material such as acryl resin, epoxy resin, phenolic resin, polyamide resin, or polyimide resin.

The upper structure 312b of the third inner barrier pattern IBT_c may include a protrusion PT disposed at a center and a trench groove G3 surrounding the protrusion PT. The trench groove G3 may be recessed to have a depth Hc1 from a top surface toward a bottom surface of the upper structure 312b. In a plan view, each of the protrusion PT and the trench groove G3 may have a circular shape. In a cross-sectional view, the upper structure 312b may include the top surface TS divided into a plurality of parts by the trench groove G3, the bottom surface BS of the trench groove G3, and the sidewall SS connecting the bottom surface BS with the top surface TS. The sidewall SS may be an inclined surface inclined at a predetermined angle with respect to the bottom surface BS.

The upper structure 312b of the third inner barrier pattern IBT_c may have a reverse taper shape with a width becoming smaller toward the bottom surface.

The organic light-emitting layer 220 may be deposited along a surface of the upper structure 312b. In a total thickness H3 of the upper structure 312b, the depth Hc1 of the trench groove G3 may be smaller than a thickness Hc2 from the bottom surface BS of the trench groove G3 to a bottom surface of the upper structure 312b. Accordingly, the organic light-emitting layer 220 may be deposited to have continuity along shapes of surfaces of the top surface TS of the upper structure 312b including the protrusion PT, the bottom surface BS exposed by the trench groove G3, and the sidewall SS. Because the upper structure 312b of the third inner barrier pattern IBT_c has the reverse taper shape, the organic light-emitting layer 220 may not be stacked on an outer side surface of the upper structure 312b.

When the upper structure 312b of the third inner barrier pattern IBT_c has a flat top surface, the organic light-emitting layer deposited on the flat top surface may have a length in a range from 5.5 μm to 5.9 μm. In this regard, as the organic light-emitting layer 220 deposited on the third inner barrier pattern IBT_c in FIG. 13 is formed along a surface of the trench groove G3, the organic light-emitting layer 220 may have a length in a range from 6.6 μm to 8 μm. Accordingly, when defining the length of the organic light-emitting layer deposited on the flat top surface as 100%, the organic light-emitting layer formed on the third inner barrier pattern IBT_c along the surface of the trench groove G3 may have a length that is increased by 30% from that in the case of being deposited on the flat top surface. In other words, the time when the moisture or the oxygen penetrates toward the display area may be further delayed compared to the case of having the flat top surface.

The trench groove G3, which is introduced to increase the length of the organic light-emitting layer in the barrier pattern BT, is desirable to be defined only in the third inner barrier pattern IBT_c without being defined in the outer barrier pattern OBT to prevent or reduce the seam from occurring. The seam may become the penetration path for gas generated in the subsequent process, or may become another penetration path for the moisture or the oxygen penetrated through the through-hole H.

On the upper structure 312b of the third inner barrier pattern IBT_c, the second encapsulation layer 253 including the organic insulating material may be deposited on the first encapsulation layer 251. Accordingly, even when the trench groove G3 is defined in the upper structure 312b of the third inner barrier pattern IBT_c, the seam may be prevented or reduced from occurring by the second encapsulation layer 253 having flowability. As the trench groove G3 is defined only in the third inner barrier pattern IBT_c, the outer barrier pattern OBT and the third inner barrier pattern IBT_c, which have the different shapes, may be disposed on the hole boundary area MA.

In one example, depending on the depth of the trench groove or the shape of the trench groove defined in the upper structure of the third inner barrier pattern, the area in which the organic light-emitting layer is disconnected may increase, thereby further increasing the effect of blocking the moisture penetration path. Hereinafter, this will be described with reference to FIGS. 14 and 15.

Referring to FIG. 14, the third inner barrier pattern IBT_c may include a trench groove G4. The trench groove G4 may have a shape surrounding the protrusion PT. The trench groove G4 may be recessed to have a depth Hd1 from the top surface toward the bottom surface of the upper structure 312b. In a cross-sectional view, the upper structure 312b may include the top surface TS divided into a plurality of parts by the trench groove G4, the bottom surface BS of the trench groove G4, and the sidewall SS connecting the bottom surface BS with the top surface TS. The sidewall SS may be an inclined surface inclined at a predetermined angle with respect to the bottom surface BS. The upper structure 312b of the third inner barrier pattern IBT_c may have a reverse taper shape with the width becoming smaller toward the bottom surface.

The organic light-emitting layer 220 may be deposited along the surface of the upper structure 312b. In a total thickness H4 of the upper structure 312b, the depth Hd1 of the trench groove G4 may be greater than a thickness Hd2 between the bottom surface BS of the trench groove G4 and the bottom surface of the upper structure 312b.

As the distance between the bottom surface BS of the trench groove G4 and the bottom surface of the upper structure 312b becomes smaller, the depth of the sidewall SS also increases. Accordingly, the organic light-emitting layer 220 may cover a portion of the sidewall SS of the trench groove G4 and expose the remaining portion of the sidewall SS close to the bottom surface BS without covering the same. The organic light-emitting layer 220 may include the first portion 220a covering the bottom surface BS of the trench groove G4 in the upper structure 312b, the second portion 220b covering the top surface TS and a portion of the sidewall SS divided into parts on both sides with the bottom surface BS interposed therebetween, and a third portion 220c covering a top surface of the protrusion PT.

Accordingly, the organic light-emitting layer 220 may be not only disconnected between third inner barrier patterns IBT_c adjacent to each other and between outer barrier patterns OBT adjacent to each other, but also at the top surface TS of the upper structure 312b of the third inner barrier pattern IBT_c and at the protrusion PT. In other words, as the area in which the organic light-emitting layer 220 is disconnected increases, the moisture or the oxygen penetrating from the outside may be prevented or reduced from penetrating toward the display area AA, or the time when the moisture or the oxygen penetrates toward the display area AA may be further delayed.

Referring to FIG. 15, in another embodiment, a trench groove G5 of the third inner barrier pattern IBT_c may have the sidewall SS having a vertical surface instead of the inclined surface with respect to the bottom surface BS. Accordingly, the organic light-emitting layer 220 may not be deposited on the sidewall SS of the trench groove G5. The organic light-emitting layer 220 may include the first portion 220a covering the bottom surface BS of the trench groove G5 in the upper structure 312b, the second portion 220b covering the top surface TS, and the third portion 220c covering the top surface of the protrusion PT. Because of the shape of the trench groove G4 in which the sidewall SS has the vertical surface with respect to the bottom surface BS, the length of the disconnected section on the sidewall SS may increase, which may further increase the delay in the time when the moisture penetrates.

According to another embodiment of the present disclosure, when the moisture or the oxygen penetrates from the outside through the cross-section of the through-hole H defined using the laser, the penetration of the moisture or the oxygen may be prevented or reduced or the time when the moisture or the oxygen diffuses may be delayed by the hole boundary area MA including the outer barrier pattern OBT, the dam pattern DM, and the third inner barrier pattern IBT_c. For example, the time when the moisture or the oxygen diffuses from the hole end HE3 toward the display area AA may be delayed for a long time by the organic light-emitting layer 220 disconnected on each structure of the outer barrier pattern OBT, the dam pattern DM, and the third inner barrier pattern IBT_c.

Accordingly, damage to the light-emitting element caused by the moisture or oxygen penetration may be blocked or delayed, thereby preventing or reducing the dark spot defect from occurring. Additionally, the decrease in the reliability of the display apparatus caused by the decrease in the luminance resulted from the defect in the light-emitting element may be prevented or reduced.

A display apparatus according to an embodiment of the present disclosure includes a display area located on a substrate and including a plurality of light-emitting elements, a first region located within the display area and including a through-hole, and a second region located between the first region and the display area, the display apparatus includes a dam pattern located on the second region between the through-hole and the display area, an outer barrier pattern disposed between the through-hole and the dam pattern, and an inner barrier pattern disposed between the dam pattern and the display area, and each of the inner barrier pattern and the outer barrier pattern has an undercut structure.

In the display apparatus according to some embodiments of the present disclosure, the inner barrier pattern may have a trench groove including a bottom surface and a sidewall surrounding the bottom surface.

In the display apparatus according to some embodiments of the present disclosure, each of the plurality of light-emitting elements may include a first electrode, a second electrode, and an organic light-emitting layer located between the first electrode and the second electrode.

In the display apparatus according to some embodiments of the present disclosure, each of the outer barrier pattern and the inner barrier pattern may include a stacked structure of a lower structure and an upper structure disposed on the lower structure, and the organic light-emitting layer may be deposited along a shape of a surface of a top surface of the upper structure, excluding a sidewall of the lower structure.

In the display apparatus according to some embodiments of the present disclosure, the outer barrier pattern may be disposed to be spaced apart from the through-hole and to surround the through-hole, and the inner barrier pattern may be disposed to be spaced apart from the dam pattern and to surround the dam pattern.

In the display apparatus according to some embodiments of the present disclosure, each of the outer barrier pattern, the inner barrier pattern, and the dam pattern may have a closed curve shape.

In the display apparatus according to some embodiments of the present disclosure, each of the outer barrier pattern, the inner barrier pattern, and the dam pattern may have a size greater than a diameter of the through-hole, and among the outer barrier pattern, the inner barrier pattern, and the dam pattern, the outer barrier pattern located closest to the through-hole may have the smallest diameter, and the inner barrier pattern located farthest from the through-hole may have the greatest diameter.

In the display apparatus according to some embodiments of the present disclosure, each of the outer barrier pattern and the inner barrier pattern may include a stacked structure of a lower structure and an upper structure disposed on the lower structure, and a top surface of the upper structure of the outer barrier pattern may have a flat surface, and the organic light-emitting layer may be deposited along a shape of a surface of a top surface of the upper structure excluding a sidewall of the lower structure in each of the outer barrier pattern and the inner barrier pattern.

In the display apparatus according to some embodiments of the present disclosure, the trench groove of the inner barrier pattern may be located in the upper structure.

In the display apparatus according to some embodiments of the present disclosure, in a total thickness of the upper structure of the inner barrier pattern, a depth of the trench groove may be smaller than a distance between the bottom surface of the trench groove and a bottom surface of the upper structure.

In the display apparatus according to some embodiments of the present disclosure, the organic light-emitting layer may be disposed to extend to have continuity on an outer side surface and the top surface of the upper structure of the inner barrier pattern and on the bottom surface and the side surface of the trench groove.

In the display apparatus according to some embodiments of the present disclosure, in a total thickness of the upper structure of the inner barrier pattern, a depth of the trench groove may be greater than a distance between the bottom surface of the trench groove and a bottom surface of the upper structure.

In the display apparatus according to some embodiments of the present disclosure, the organic light-emitting layer may cover an outer side surface and the top surface of the upper structure of the inner barrier pattern and the bottom surface of the trench groove, and cover a portion of the sidewall of the trench groove extending from the top surface, so that the organic light-emitting layer may be disconnected from the bottom surface of the trench groove.

In the display apparatus according to some embodiments of the present disclosure, the trench groove may have the sidewall having a vertical surface with respect to the bottom surface.

In the display apparatus according to some embodiments of the present disclosure, the outer barrier pattern may include a stacked structure of a lower structure and an upper structure disposed on the lower structure and having a flat surface, the inner barrier pattern may further include a protrusion, and the trench groove is defined to surround the protrusion, and the organic light-emitting layer may be stacked on the outer barrier pattern and the inner barrier pattern.

In the display apparatus according to some embodiments of the present disclosure, the inner barrier pattern may have a reverse taper shape with a width becoming smaller downward.
A display apparatus according to another embodiment of the present disclosure may include a display area located on a substrate and including a plurality of light-emitting elements, a first region located within the display area and including a through-hole, and a second region located between the first region and the display area, the display apparatus includes a dam pattern located on the second region between the through-hole and the display area, an outer barrier pattern disposed between the through-hole and the dam pattern, each of the plurality of light-emitting elements includes a first electrode, a second electrode, and an organic light-emitting layer located between the first electrode and the second electrode, and the organic light-emitting layer is disconnected on each of the inner barrier pattern and the outer barrier pattern.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a display area located on a substrate and including a plurality of light-emitting elements;
a first region located within the display area and including a through-hole; and
a second region located between the first region and the display area,
wherein the display apparatus includes a dam pattern located on the second region between the through-hole and the display area, an outer barrier pattern disposed between the through-hole and the dam pattern, and an inner barrier pattern disposed between the dam pattern and the display area, and
wherein each of the inner barrier pattern and the outer barrier pattern has an undercut structure.

2. The display apparatus of claim 1, wherein the inner barrier pattern has a trench groove including a bottom surface and a sidewall surrounding the bottom surface.

3. The display apparatus of claim 2, wherein each of the plurality of light-emitting elements includes a first electrode, a second electrode, and an organic light-emitting layer located between the first electrode and the second electrode.

4. The display apparatus of claim 3, wherein each of the outer barrier pattern and the inner barrier pattern includes a stacked structure of a lower structure and an upper structure disposed on the lower structure,
wherein the organic light-emitting layer is deposited along a shape of a surface of a top surface of the upper structure, excluding a sidewall of the lower structure.

5. The display apparatus of claim 1, wherein the outer barrier pattern is disposed to be spaced apart from the through-hole and to surround the through-hole, and the inner barrier pattern is disposed to be spaced apart from the dam pattern and to surround the dam pattern.

6. The display apparatus of claim 5, wherein each of the outer barrier pattern, the inner barrier pattern, and the dam pattern has a closed curve shape.

7. The display apparatus of claim 6, wherein each of the outer barrier pattern, the inner barrier pattern, and the dam pattern has a size greater than a diameter of the through-hole,
wherein among the outer barrier pattern, the inner barrier pattern, and the dam pattern, the outer barrier pattern located closest to the through-hole has the smallest diameter, and the inner barrier pattern located farthest from the through-hole has the greatest diameter.

8. The display apparatus of claim 3, wherein each of the outer barrier pattern and the inner barrier pattern includes a stacked structure of a lower structure and an upper structure disposed on the lower structure,
wherein a top surface of the upper structure of the outer barrier pattern has a flat surface, and the organic light-emitting layer is deposited along a shape of a surface of a top surface of the upper structure excluding a sidewall of the lower structure in each of the outer barrier pattern and the inner barrier pattern.

9. The display apparatus of claim 8, wherein the trench groove of the inner barrier pattern is located in the upper structure.

10. The display apparatus of claim 9, wherein in a total thickness of the upper structure of the inner barrier pattern, a depth of the trench groove is smaller than a distance between the bottom surface of the trench groove and a bottom surface of the upper structure.

11. The display apparatus of claim 10, wherein the organic light-emitting layer is disposed to extend to have continuity on an outer side surface and the top surface of the upper structure of the inner barrier pattern and on the bottom surface and the side surface of the trench groove.

12. The display apparatus of claim 9, wherein in a total thickness of the upper structure of the inner barrier pattern, a depth of the trench groove is greater than a distance between the bottom surface of the trench groove and a bottom surface of the upper structure.

13. The display apparatus of claim 12, wherein the organic light-emitting layer covers an outer side surface and the top surface of the upper structure of the inner barrier pattern and the bottom surface of the trench groove, and covers a portion of the sidewall of the trench groove extending from the top surface, so that the organic light-emitting layer is disconnected from the bottom surface of the trench groove.

14. The display apparatus of claim 2, wherein the trench groove has the sidewall having a vertical surface with respect to the bottom surface.

15. The display apparatus of claim 3, wherein the outer barrier pattern includes a stacked structure of a lower structure and an upper structure disposed on the lower structure and having a flat surface,
wherein the inner barrier pattern further includes a protrusion, and the trench groove is defined to surround the protrusion,
wherein the organic light-emitting layer is stacked on the outer barrier pattern and the inner barrier pattern.

16. The display apparatus of claim 14, wherein the inner barrier pattern has a reverse taper shape with a width becoming smaller downward.

17. The display apparatus of claim 14, wherein in a total thickness of an upper structure of the inner barrier pattern, a depth of the trench groove is smaller than a distance between the bottom surface of the trench groove and a bottom surface of the upper structure.

18. The display apparatus of claim 14, wherein in a total thickness of an upper structure of the inner barrier pattern, the depth of the trench groove is greater than a distance between the bottom surface of the trench groove and a bottom surface of the upper structure.

19. The display apparatus of claim 14, wherein the trench groove has the sidewall having a vertical surface with respect to the bottom surface.

20. A display apparatus, comprising:
a display area located on a substrate and including a plurality of light-emitting elements;
a first region located within the display area and including a through-hole; and
a second region located between the first region and the display area,
wherein the display apparatus includes a dam pattern located on the second region between the through-hole and the display area, an outer barrier pattern disposed between the through-hole and the dam pattern, and an inner barrier pattern disposed between the dam pattern and the display area, and
wherein each of the plurality of light-emitting elements includes a first electrode, a second electrode, and an organic light-emitting layer located between the first electrode and the second electrode, and
wherein the organic light-emitting layer is disconnected on each of the inner barrier pattern and the outer barrier pattern.

21. The display apparatus of claim 20, wherein the inner barrier pattern has a trench groove including a bottom surface and a sidewall surrounding the bottom surface.
